(19) United States
(12) Patent Application Publication
(10) Pub. No.: US 2024/0318037 A1
(43) Pub. Date: Sep. 26, 2024

(54) SLURRY COMPOSITION AND METHOD OF MANUFACTURING SEMICONDUCTOR DEVICE BY USING THE SAME

(71) Applicant: SAMSUNG ELECTRONICS CO., LTD., Suwon-si (KR)

(72) Inventors: Yearin Byun, Suwon si (KR); Eunock Kim, Anseong si (KR); Suyeong Jung, Anseong si (KR); Hyungoo Kong, Anseong si (KR); Inkwon Kim, Suwon si (KR); Sanghyun Park, Suwon si (KR)

(73) Assignee: Kctech Co.,Ltd., Anseong si (KR)

(21) Appl. No.: 18/609,795

(22) Filed: Mar. 19, 2024

(30) Foreign Application Priority Data
Mar. 24, 2023 (KR) 10-2023-0039269
May 30, 2023 (KR) 10-2023-0069451

(51) Int. Cl. C09G 1/02; H01L 21/3205; H01L 21/321

(52) U.S. Cl. CPC C09G 1/02; H01L 21/3212; H01L 21/32051

(57) ABSTRACT

The present disclosure relates to slurry compositions used for chemical mechanical polishing of a metal film. An example slurry composition includes abrasive particles, deionized water, and an oxidizer. The oxidizer includes iodine, and is a temperature-sensitive oxidizer capable of controlling both a static etch rate and a removal rate of the metal film when a polishing temperature during the chemical mechanical polishing is about 5° C. to about 100° C.

### CROSS-REFERENCE TO RELATED APPLICATIONS

This application claims priority under 35 U.S.C. § 119 to Korean Patent Application Nos. 10-2023-0039269, filed on Mar. 24, 2023, and 10-2023-0069451, filed on May 30, 2023, in the Korean Intellectual Property Office, the disclosures of which are incorporated by reference herein in their entireties.

### BACKGROUND

With the development of the electronics industry and consumer demand, the degree of integration of semiconductor devices included in electronic devices is increasing. Accordingly, line widths and pitches of metal wiring layers included in semiconductor devices are being miniaturized. To manufacture metal wiring layers included in semiconductor devices, a chemical mechanical polishing process is performed for planarizing metal films by using a slurry composition for chemical mechanical polishing. Recently, as the line widths and pitches of metal wiring layers have been refined, there is a demand for a slurry composition capable of securing the flatness of metal wiring layers while having a high removal rate.

### SUMMARY

The present disclosure relates to slurry compositions, including a slurry composition capable of improving the flatness of a metal film subjected to chemical mechanical polishing while reducing the time for chemical mechanical polishing of the metal film as well as a slurry composition capable of preventing discoloration and contamination of a chemical mechanical polishing apparatus used when performing chemical mechanical polishing of a metal film, and methods of manufacturing semiconductor devices using the same.

In some implementations, a slurry composition is used for chemical mechanical polishing of a metal film, the slurry composition including abrasive particles, deionized water, and an oxidizer, wherein the oxidizer including iodine is a temperature-sensitive oxidizer capable of controlling both a static etch rate and a removal rate of the metal film when the polishing temperature during the chemical mechanical polishing is about 5° C. to about 100° C.

In some implementations, a slurry composition is used for chemical mechanical polishing of a metal film, the slurry composition including abrasive particles, deionized water, an oxidizer, and an adsorbent, wherein the oxidizer includes iodine, and the adsorbent is capable of adsorbing iodine generated from the oxidizer.

In some implementations, a slurry composition is used for chemical mechanical polishing of a metal film including tungsten (W), the slurry composition including abrasive particles, deionized water, an oxidizer including iodine, an adsorbent including porous material, and a pH adjusting agent, wherein the oxidizer including iodine is a temperature-sensitive oxidizer capable of controlling both a static etch rate and a removal rate of the metal film when the polishing temperature during the chemical mechanical polishing is about 5° C. to about 100° C., and the adsorbent is an adsorbent capable of adsorbing iodine generated from the oxidizer.

In some implementations, a method of manufacturing a semiconductor device includes forming a metal film on a substrate, and polishing the metal film by a chemical mechanical polishing process using a slurry composition, wherein the slurry composition used for chemical mechanical polishing of the metal film includes abrasive particles, deionized water, an oxidizer including iodine, and an adsorbent, wherein the oxidizer is a temperature-sensitive oxidizer capable of controlling both a static etch rate and a removal rate of the metal film when the polishing temperature during the chemical mechanical polishing is about 5° C. to about 100° C., and the adsorbent is an adsorbent capable of adsorbing iodine generated from the oxidizer.

### BRIEF DESCRIPTION OF THE DRAWINGS

Implementations will be more clearly understood from the following detailed description, taken in conjunction with the accompanying drawings.

FIG. 1 is a schematic cross-sectional view of an example chemical mechanical polishing apparatus using a slurry composition.

FIG. 2 is a schematic plan view of an example chemical mechanical polishing apparatus using a slurry composition.

FIG. 3 is a flowchart illustrating an example method of manufacturing a semiconductor device using a slurry composition.

FIGS. 4-6 are cross-sectional views illustrating an example method of manufacturing a semiconductor device using a slurry composition.

FIG. 7 is an example diagram illustrating a change in polishing temperature over time during chemical mechanical polishing using a slurry composition.

FIG. 8 is an example diagram illustrating a static etch rate (SER) of a metal film according to the temperature of a slurry composition, and an SER of a metal film according to the temperature of a slurry composition according to a comparative example.

FIG. 9 is an example diagram illustrating a removable rate (RR) of a metal film according to the temperature of a slurry composition, and an RR of a metal film according to the temperature of a slurry composition according to a comparative example.

FIG. 10 is an example diagram illustrating a degree of iodine adsorption by an adsorbent included in each slurry composition, and a degree of iodine adsorption by an adsorbent included in a slurry composition according to a comparative example.

### DETAILED DESCRIPTION

Hereinafter, implementations will be described in detail with reference to the accompanying drawings. The same reference numerals are used for the same components in the drawings, and duplicate descriptions thereof are omitted.

A slurry composition according to some implementations may include abrasive particles, deionized water, an oxidizer, and an adsorbent.

In some implementations, the slurry composition may be a slurry composition for chemical mechanical polishing which is used for chemical mechanical polishing of a metal film.

In some implementations, the metal film subjected to chemical mechanical polishing using the slurry composition may include tungsten, molybdenum, or a combination thereof.

In some implementations, the abrasive particles may be at least one selected from the group consisting of silica, alumina, ceria, titania, zirconia, magnesia, germania, and mangania. For example, the abrasive particles may be silica.

In some implementations, the concentration of the abrasive particles may be greater than about 0 wt % and less than about 10 wt % based on the total weight of the slurry composition. For example, the concentration of the abrasive particles is about 0.1 wt % to about 10 wt %, about 0.1 wt % to about 7 wt %, about 0.1 wt % to about 5 wt %, or about 0.1 wt % to about 1 wt %.

In some implementations, the oxidizer may be a temperature-sensitive oxidizer capable of controlling both a static etch rate (SER) and a removal rate (RR) of the metal film when the polishing temperature during chemical mechanical polishing is about 5° C. to about 100° C. For example, the oxidizer may be a temperature-sensitive oxidizer capable of controlling both the SER and the RR of the metal film when the polishing temperature during chemical mechanical polishing is about 60° C.

In some implementations, the oxidizer may include iodine. For example, the oxidizer may be at least one selected from the group consisting of iodate and periodate. In some implementations, the iodate may be any one of potassium iodate, sodium iodate, calcium iodate, and magnesium iodate. In some implementations, the periodate is at least one of sodium periodate, periodic acid, and potassium periodate.

In some implementations, the concentration of the oxidizer is about 1 wt % to about 5 wt % based on the total weight of the slurry composition. For example, the concentration of the oxidizer is about 2 wt % to about 5 wt % or about 3 wt % to about 5 wt % based on the total weight of the slurry composition. When the concentration of the oxidizer is less than about 1 wt %, the RR of the metal film may decrease. When the concentration of the oxidizer is greater than about 5 wt %, the SER of the metal film may increase and the flatness of the metal film may be deteriorated.

In some implementations, the adsorbent may adsorb iodine generated from the oxidizer during the chemical mechanical polishing process. In some implementations, the adsorbent may include porous material. In some implementations, the porous material may include a plurality of pores having a diameter of about 0.01 nm to about 10 nm. For example, the porous material may include a plurality of pores having a diameter of about 0.01 nm to about 10 nm, about 0.1 nm to about 3 nm, about 0.3 nm to about 3 nm, or about 0.3 nm to about 1 nm. In some implementations, the adsorbent may be at least one selected from the group consisting of a metal organic framework (MOF), a zeolite, and an activated carbon. For example, the adsorbent may be a zeolite.

In some implementations, the concentration of the adsorbent may be greater than about 0 wt % and less than or equal to about 1 wt % based on the total weight of the slurry composition. For example, the concentration of the adsorbent may be about 0.1 wt % to about 1 wt %, or about 0.5 wt % to about 1 wt % based on the total weight of the slurry composition. When the concentration of the adsorbent is greater than about 1 wt %, defects such as scratches may occur on the surface of the metal film due to the adsorbent.

In some implementations, the slurry composition may further include a pH adjusting agent. The pH adjusting agent may be at least one selected from the group consisting of, for example, lithium hydroxide, sodium hydroxide, potassium hydroxide, cesium hydroxide, sulfuric acid, nitric acid, hydrogen chloride, and phosphoric acid. For example, the pH adjusting agent may be lithium hydroxide. In some implementations, the pH adjusting agent may adjust the slurry composition to have a pH selected from about 1 to about 5. For example, the pH adjusting agent may adjust the slurry composition to have a pH of about 1 to about 3, about 2 to about 3, or about 2.1 to about 2.5.

In some implementations, the slurry composition may further include a catalyst. The catalyst may improve the oxidizing ability of the slurry composition and increase the removal rate of the metal film subjected to polishing. The catalyst may be at least one selected from the group consisting of ferric nitrate, potassium ferricyanide, iron chloride, iron sulfate, iron fluoride, iron bromide, copper chloride, copper fluoride, and copper bromide.

When the catalyst is included in the slurry composition, the concentration of the catalyst may be about 0.001 wt % to about 0.1 wt %, for example, about 0.001 wt % to about 0.01 wt %, based on the total weight of the slurry composition.

In some implementations, the slurry composition may further include a corrosion inhibitor. The corrosion inhibitor may selectively adhere to a surface of a metal contained in the metal film subjected to polishing, and may effectively suppress excessive corrosion of the metal film while maintaining a good RR of the metal film. The corrosion inhibitor may be, for example, at least one selected from the group consisting of triazole and derivatives thereof, and benzene triazole and derivatives thereof.

When the corrosion inhibitor is included in the slurry composition, the concentration of the corrosion inhibitor is about 0.001 wt % to about 1 wt %, for example, about 0.001 wt % to about 0.5 wt %, based on the total weight of the slurry composition.

In some implementations, the slurry composition may further include a dispersion stabilizer. The dispersion stabilizer may ensure good dispersion of the abrasive particles in the slurry composition. The dispersion stabilizer may be at least one selected from the group consisting of, for example, ethylene oxide, ethylene glycol, glycol distearate, glycol monostearate, glycol polymerate, glycol ethers, alcohols containing alkylamine, compounds containing polymerate ether, vinyl pyrrolidone, celluloses, and ethoxylate.

When the dispersion stabilizer is included in the slurry composition, the concentration of the dispersion stabilizer may be about 0.001 wt % to about 1 wt %, for example, about 0.001 wt % to about 0.5 wt %, based on the total weight of the slurry composition.

In some implementations, the slurry composition may further include a biocide. The biocide may prevent contamination of the slurry composition or the metal film subject to polishing to which the slurry composition is applied, with microorganisms. The biocide may be at least one selected from the group consisting of, for example, organo tin compounds, salicylanilide, mercaptan, quaternary ammonium compounds, hydrogen peroxide, sodium chloride, and sodium hypochlorite.

When the biocide is included in the slurry composition, the concentration of the biocide may be about 0.001 wt % to about 10 wt % based on the total weight of the slurry composition. In some implementations, the concentration of the biocide may be about 0.001 wt % to about 5 wt %, about 0.001 wt % to about 3 wt %, or about 0.001 wt % to about 1 wt %.

According to some implementations, the slurry composition may include a temperature-sensitive oxidizer including iodine and capable of controlling both the SER and the RR of the metal film subjected to chemical mechanical polishing when the polishing temperature during chemical mechanical polishing is about 5° C. to about 100° C. Accordingly, when the chemical mechanical polishing process is performed using the slurry composition, the flatness of the metal film subjected to polishing may be improved while reducing the removal time.

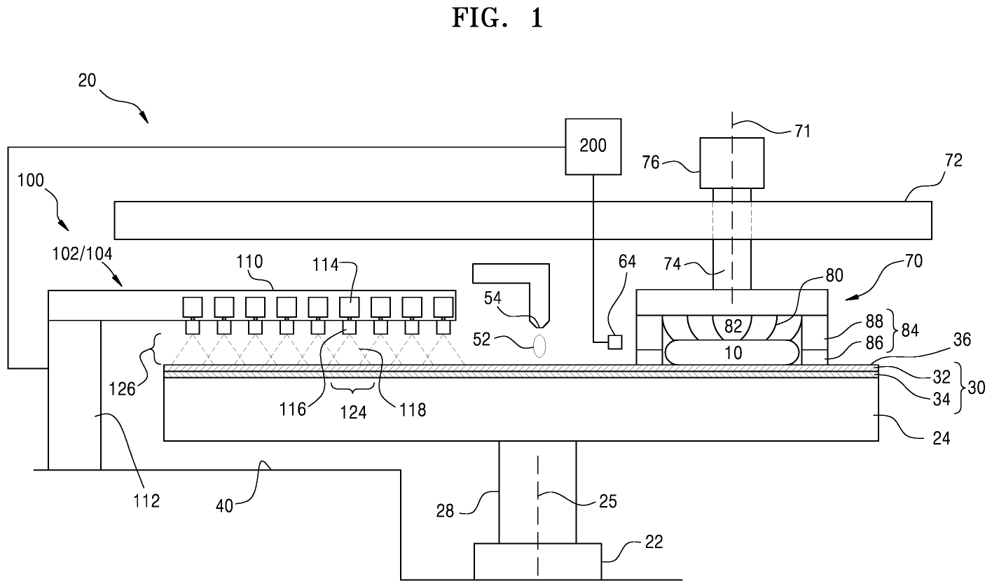

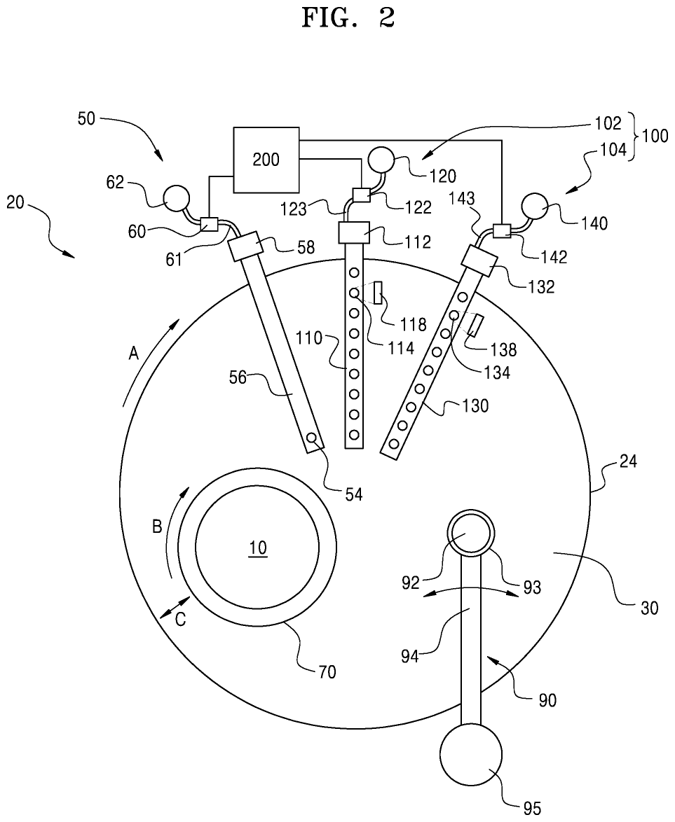

In addition, according to some implementations, the slurry composition may include the adsorbent, and the adsorbent may adsorb iodine generated from the oxidizer during the chemical mechanical polishing process. Accordingly, it is possible to prevent a chemical mechanical polishing apparatus 20 (see FIGS. 1 and 2) from being discolored and contaminated by iodine generated from the oxidizer after the chemical mechanical polishing is performed. Hereinafter, the chemical mechanical polishing apparatus 20 using a slurry composition according to some implementations are described.

FIG. 1 is a schematic cross-sectional view of an example chemical mechanical polishing apparatus 20 using a slurry composition. FIG. 2 is a schematic plan view of an example chemical mechanical polishing apparatus 20 using a slurry composition.

Referring to FIGS. 1 and 2, the chemical mechanical polishing apparatus 20 may include a rotatable disc-shaped platen 24 on which an abrasive pad 30 is positioned. The chemical mechanical polishing apparatus 20 may also be referred to as a polishing station. The platen 24 may rotate about a central axis 25. The platen 24 may rotate about a central axis 25 as indicated by an arrow A in FIG. 2. A motor 22 may rotate a drive shaft 28 to rotate the platen 24.

In some implementations, the abrasive pad 30 may be a double abrasive pad having a lower abrasive pad 34 and an upper abrasive pad 32. The upper abrasive pad 32 may include a softer material than the lower abrasive pad 34. The chemical mechanical polishing apparatus 20 may include an abrasive liquid supply system 50 for supplying a slurry composition 52 onto the abrasive pad 30 via a port 54.

The abrasive liquid supply system 50 may include an arm 56 supported by a base 58 to extend over the platen 24. The port 54 may be positioned at an end of the arm 56. The port 54 may be coupled via a control valve 60 and a pipe 61 to an abrasive liquid supplier 62, for example, a reservoir or a tank for storing the slurry composition 52. The slurry composition 52 may have substantially the same composition as described above with respect to the slurry composition according to some implementations.

A carrier head 70 may operate while supporting a substrate 10 in contact with the abrasive pad 30. As described below, the substrate 10 may be a substrate structure having a metal film formed thereon. The carrier head 70 may be referred to as a polishing head. The carrier head 70 may be coupled to a support structure 72. The carrier head 70 may be rotated about an axis 71 by being connected to a rotation motor 76 by a drive shaft 74.

The carrier head 70 may include a flexible membrane 80 having a substrate mounting surface for contacting a back side (or rear surface) of the substrate 10, and a pressurization chamber 82 for applying pressure onto the substrate 10. The carrier head 70 may include a retaining ring 84 for supporting (holding) the substrate 10. The retaining ring 84 may include a lower retaining ring 86 and an upper retaining ring 88.

During operation of the chemical mechanical polishing apparatus 20, the platen 24 may be rotated about the central axis 25, and the carrier head 70 may be rotated about the central axis 71 as shown by an arrow B in FIG. 2, and may be moved laterally across the top surface of the abrasive pad 30 as shown by an arrow C in FIG. 2.

The chemical mechanical polishing apparatus 20 may include a pad conditioner 90 having a conditioner disk 92 held by a conditioner head 93 at an end of a conditioner arm 94. The conditioner disk 92 may be used to maintain the surface roughness of the abrasive pad 30. The conditioner arm 94 may be supported by a conditioner base 95.

The chemical mechanical polishing apparatus 20 may include a temperature sensor 64 for monitoring the temperature of the abrasive pad 30 and/or the slurry composition 52 above the abrasive pad 30. For example, the temperature sensor 64 may be an infrared (IR) sensor, e.g., IR camera, positioned above the abrasive pad 30 and configured to measure the temperature of the abrasive pad 30 and/or the slurry composition 52 above the abrasive pad 30.

The temperature sensor 64 may be configured to measure temperatures at multiple points along the radius of the abrasive pad 30 to create a radial temperature profile. For example, the IR camera of the temperature sensor 64 may have a field of view that spans the radius of the abrasive pad 30.

In some implementations, the temperature sensor 64 may be a contact sensor rather than the non-contact sensor illustrated in FIG. 1. For example, the temperature sensor 64 may be a thermocouple or IR thermometer located above or in the platen 24. The temperature sensor 64 may be in direct contact with the abrasive pad 30. In some implementations, a plurality of temperature sensors 64 may be spaced apart at radial positions of the abrasive pad 30 to provide the temperatures at multiple points along the radius of the abrasive pad 30.

The temperature sensor 64 is illustrated in FIG. 1 as being positioned to monitor the temperature of the abrasive pad 30 and/or the slurry composition 52 above the abrasive pad 30, but is not limited thereto, and the temperature sensor 64 may be located inside the carrier head 70 to measure the temperature of the substrate 10. The temperature sensor 64 may be a contact sensor that directly contacts the substrate 10, that is, a semiconductor wafer.

The chemical mechanical polishing apparatus 20 may include a temperature control system 100 for controlling the temperature of the abrasive pad 30 and/or the slurry composition 52 above the abrasive pad 30. The temperature control system 100 may deliver a temperature-controlled fluid onto an abrasive surface 36 of the abrasive pad 30. The temperature control system 100 may deliver the temperature-controlled fluids 118, 138 onto the slurry composition 52 already present on the abrasive pad 30. The temperature control system 100 may include a heating system 102 and a cooling system 104.

The heating system 102 may deliver a heating fluid 118, for example, hot water or steam. The cooling system 104 may deliver a cooling fluid 138, for example, cold water or cooling air.

The heating fluid 118 and the cooling fluid 138 may be delivered through nozzles 116 and apertures 114, and 134 provided by arms 110, and 130.

In some implementations, the heating system 102 may include the arm 110 extending over the platen 24 and the abrasive pad 30 from the edge of the abrasive pad 30 to the center of or at least near the center of the abrasive pad 30. The arm 110 may be supported by a base 112. The base 112 may be supported on the same frame 40 as the platen 24.

The base 112 may include one or more actuators, such as linear actuators to raise or lower the arm 110, and/or rotary actuators to swing the arm 110 laterally over the platen 24. The arm 110 may be positioned to avoid collision with other hardware components such as the carrier head 70, the conditioner disk 92, the arm 56 for supplying chemical mechanical polishing slurry, and the arm 130 for supplying cooling fluid, etc.

The plurality of apertures 114 are formed in the lowermost surface of the arm 110. The apertures 114 may be configured to direct the heating fluid 118, e.g., gas or vapor (or steam), onto the abrasive pad 30. In some implementations, the apertures 114 may be connected to the nozzles 116 that direct the heating fluid 118 discharged in the form of spray onto the abrasive pad 30. Although the apertures 114 and the nozzles 116 are separately illustrated in FIG. 1, the apertures 114 and the nozzles 116 may be one body, or the heating fluid 118 may be discharged in the form of spray directly through the apertures 114 which are not connected to the nozzles 116.

The apertures 114 may direct the heating fluid 118 in a radial pattern 124 on the abrasive pad 30. In FIG. 2, the apertures 114 are illustrated as being spaced apart at regular intervals, but the concept is not limited thereto. For example, the apertures 114 may be more densely clustered toward the center of the abrasive pad 30. Although FIG. 2 illustrates nine apertures 114, there may be more or less apertures 114 than nine apertures 114.

The arm 110 may be supported by the base 112 to be spaced apart from the abrasive pad 30. A distance 126 between the apertures 114 (and/or nozzles 116) and the abrasive pad 30 may be about 0.5 mm to about 5 mm. The distance 126 may be selected so that the heat of the heating fluid 118 does not significantly dissipate before reaching the abrasive pad 30. For example, the distance 126 may be selected so that the heating fluid 118 discharged from the apertures 114 does not condense before reaching the abrasive pad 30.

The heating system 102 may include a source 120 of the heating fluid 118, and the source 120 may be connected to the arm 110 via a control valve 122 and a fluid pipe 123. In some implementations, the source 120 may be a steam generator, for example, a vessel in which water is boiled to produce steam gas.

The heating fluid 118 may be mixed with another gas (e.g., air), and/or liquid (e.g., heated water), or the heating fluid 118 may be substantially pure steam. When steam is used as the heating fluid 118 and is generated from the source 120, the temperature of the steam may be about 90° C. to about 200° C. The temperature of the steam may be about 90° C. to about 150° C. when the steam is dispensed through the apertures 114, for example, due to heat loss in transit. In some implementations, the steam may be delivered through the apertures 114 at a temperature of about 60° C. to about 100° C., e.g., about 60° C. to about 75° C.

The chemical mechanical polishing apparatus 20 may include a cooling system 104. The cooling system 104 may be configured similarly to the heating system 102 as described above. The arm 130 may be supported by a base 132. The arm 130 may be connected to a source 140 via a control valve 142 and a pipe 143. However, the source 140 is a source of the cooling fluid 138, and the cooling system 104 may supply the cooling fluid 138 in the form of spray onto the abrasive pad 30.

The cooling fluid 138 may be a liquid, for example, water below about 20° C., gas below about 20° C., or a mixture of liquid and gas. The cooling fluid may be air with aerosolized water droplets. The apertures 134 may have the same configuration as the apertures 114 for supplying the heating fluid described above. The apertures 134 may have the same connection configuration as the nozzles 116 described above.

The chemical mechanical polishing apparatus 20 may include a controller 200 for controlling the operation of various components, for example, the abrasive liquid supply system 50 and the temperature control system 100. The controller 200 may be configured to receive temperature readings from the temperature sensor 64. The controller 200 may compare the measured temperature to a target temperature, and may control the control valves 122 and/or 142 to control the flow rate of heating fluid and/or cooling fluid onto the abrasive pad 30 to achieve the target temperature.

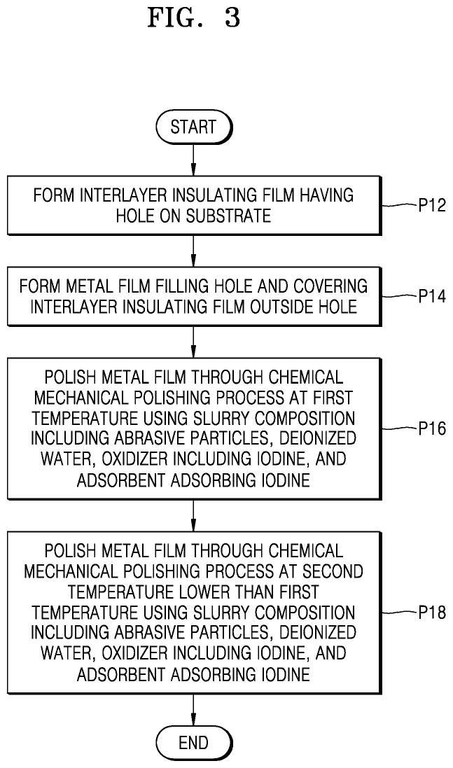

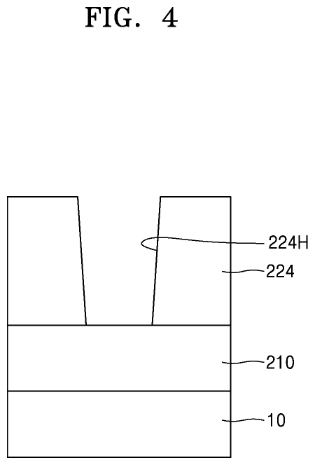

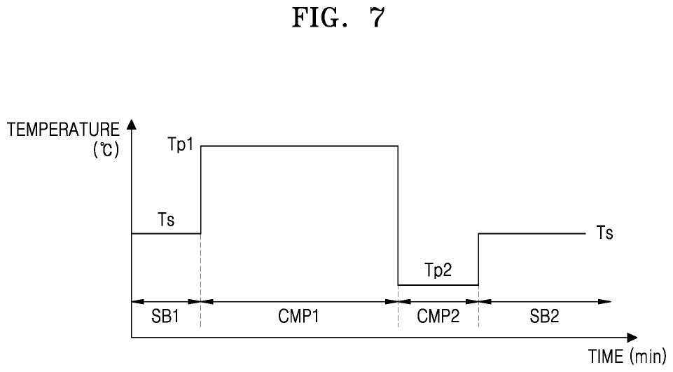

FIG. 3 is a flowchart illustrating an example method of manufacturing a semiconductor device using a slurry composition. FIGS. 4-6 are cross-sectional views illustrating an example method of manufacturing a semiconductor device using a slurry composition. FIG. 7 is an example diagram illustrating a change in polishing temperature over time during chemical mechanical polishing using a slurry composition.

Referring to FIGS. 3 and 4, in a process P12, a lower structure 210 may be formed on a substrate 10 and an interlayer insulating film 224 having a hole 224H may be formed on the lower structure 210.

The substrate 10 may include a semiconductor such as Si or Ge, or a compound semiconductor such as SiGe, SiC, GaAs, InAs, or InP. The substrate 10 may include a conductive region. The conductive region may include a well doped with impurities, a structure doped with impurities, or a conductive layer.

The lower structure 210 may include an insulating film including a silicon oxide film, a silicon nitride film, or a combination thereof. In some implementations, the lower structure 210 may include various conductive regions, such as a wiring layer, a contact plug, a transistor, and the like, and insulation patterns that insulate those from each other. In some implementations, the lower structure 210 may be omitted.

In some implementations, to form the interlayer insulating film 224 having the hole 224H, the interlayer insulating film 224 may be formed first on the lower structure 210, and then the hole 224H exposing the conductive region of the lower structure 210 may be formed through the interlayer insulating film 224.

In some implementations, the interlayer insulating film 224 may include a silicon oxide film. For example, the interlayer insulating film 224 may include plasma enhanced oxide (PEOX), tetraethyl orthosilicate (TEOS), boro TEOS (BTEOS), phosphorous TEOS (PTEOS), boro phospho TEOS (BPTEOS), boro silicate glass (BSG), or phospho silicate glass (PSG), boro phospho silicate glass (BPSG), or a combination thereof. Alternatively, the interlayer insulating film 224 may include an ultra-low K (ULK) film having an ultra-low dielectric constant K of about 2.2 to about 2.4. The ULK film may include, for example, a SiOCN film, a SiOC film, a SiCOH film, or a combination thereof.

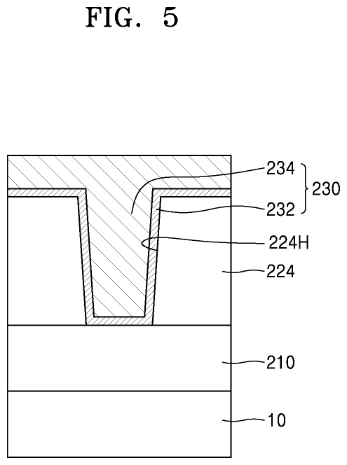

Referring to FIGS. 3 and 5, in a process P14, a metal film 230 may be formed to fill the hole 224H of the interlayer insulating film 224 and cover the interlayer insulating film 224 outside the hole 224H. The metal film 230 may be electrically connected to the conductive region of the lower structure 210.

The metal film 230 may include a conductive barrier pattern 232 which conformally covers the inner wall of the hole 224H and the upper surface of the interlayer insulating film 224, and a metal pattern 234 which fills the hole 224H on the conductive barrier pattern 232 and covers the upper surface of the interlayer insulating film 224. In some implementations, the conductive barrier pattern 232 may include Ti, TiN, Ta, TaN, or a combination thereof. The metal pattern 234 may include copper, tungsten, aluminum, cobalt, molybdenum, or a combination thereof. For example, the conductive barrier pattern 232 may include TiN and the metal pattern 234 may include tungsten, but they are not limited thereto.

In some implementations, a process of physical vapor deposition (PVD), chemical vapor deposition (CVD), atomic layer deposition (ALD), electroplating, or a combination thereof may be used to form the conductive barrier pattern 232 and the metal pattern 234.

In some implementations, the metal film 230 may be configured to be connected to the conductive region formed on the substrate 10, for example, a source/drain region or a gate electrode of a transistor, a bit line, a wiring layer, and the like.

Referring to FIGS. 3, 6, and 7, in processes P16 and P18, chemical mechanical polishing of the metal film 230 using a slurry composition SC may be performed on the abrasive pad 30 of the chemical mechanical polishing apparatus 20 illustrated in FIGS. 1 and 2. The slurry composition SC may have substantially the same composition as described above with respect to the slurry composition according to some implementations.

In some implementations, the chemical mechanical polishing process may include a first standby stage SB1, a first chemical mechanical polishing stage CMP1, a second chemical mechanical polishing stage CMP2, and a second standby stage SB2.

The first standby stage SB1 and the second standby stage SB2 may be stages before or after the chemical mechanical polishing of the metal film 230 using the slurry composition SC is performed. The polishing temperature, i.e., a temperature Ts of the slurry composition SC in the first standby stage SB1 and the second standby stage SB2 may be, for example, about 20° C.

The first chemical mechanical polishing stage CMP1 may be a first chemical mechanical polishing stage of the metal film 230 by raising the temperature Ts of the slurry composition SC in the first standby stage SB1 to a first temperature Tp1. In the first chemical mechanical polishing stage CMP1, the metal film 230 may be mechanically worn and chemically etched by the abrasive pad 30 of the chemical mechanical polishing apparatus 20 illustrated in FIGS. 1 and 2 and the slurry composition SC having the first temperature Tp1. The temperature of the slurry composition SC may be raised by the heating system 102 of the chemical mechanical polishing apparatus 20 illustrated in FIGS. 1 and 2. In some implementations, the first temperature Tp1 of the slurry composition SC in the first chemical mechanical polishing stage CMP1 may be about 40° C. to about 100° C.

The second chemical mechanical polishing stage CMP2 may be a second chemical mechanical polishing stage of the metal film 230 by lowering the first temperature Tp1 of the slurry composition SC in the first chemical mechanical polishing stage CMP1 to a second temperature Tp2. In the second chemical mechanical polishing stage CMP2, the metal film 230 may be mechanically worn and chemically etched by the abrasive pad 30 of the chemical mechanical polishing apparatus 20 illustrated in FIGS. 1 and 2 and the slurry composition SC having the second temperature Tp2. The temperature of the slurry composition SC may be lowered by the cooling system 104 of the chemical mechanical polishing apparatus 20 illustrated in FIGS. 1 and 2. In some implementations, the second temperature Tp2 of the slurry composition SC in the second chemical mechanical polishing stage CMP2 may be about 5° C. to about 40° C.

The metal pattern 234 included in the metal film 230 subjected to the first chemical mechanical polishing stage CMP1 and the second chemical mechanical polishing stage CMP2 may be recessed in a direction perpendicular to the upper surface of the substrate 10. Accordingly, the metal pattern 234 may have a recess depth Rd in the vertical direction. The recess depth Rd may be changed depending on the slurry composition used in the first chemical mechanical polishing stage CMP1 and the second chemical mechanical polishing stage CMP2. For example, when the slurry composition according to some implementations are used, the recess depth Rd may be low because the SER of the metal film is maintained relatively low despite the temperature increase of the slurry composition. When the recess depth Rd is low, flatness of the metal film may be improved.

In FIG. 7, it is illustrated that the temperature of the slurry composition SC rapidly increases from the temperature Ts in the first standby stage SB1 to the first temperature Tp1, and rapidly decreases from the first temperature Tp1 to the second temperature Tp2, but the concept is not limited thereto. For example, the temperature of the slurry composition SC may gradually increase from the temperature Ts in the first standby stage SB1 to the first temperature Tp1, and may gradually decrease from the first temperature Tp1 to the second temperature Tp2.

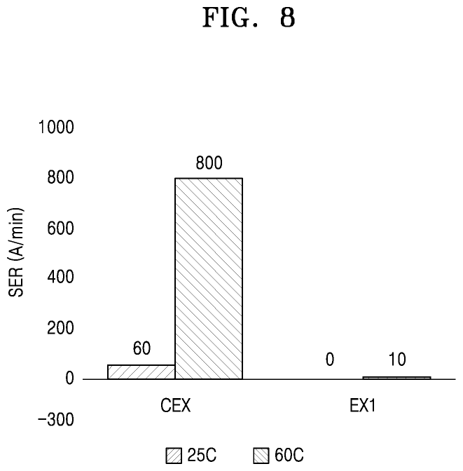

Hereinafter, the effect of the slurry composition according to some implementations is described in more detail with reference to FIGS. 8 to 10.

FIG. 8 is an example diagram illustrating a SER of a metal film according to the temperature of a slurry composition EX1, and a SER of a metal film according to the temperature of a slurry composition CEX according to a comparative example. In FIG. 8, the SERs are obtained by putting substrates into the slurry composition EX1 according to some implementations and the slurry composition CEX according to the comparative example, respectively, to etch the metal films, and measuring the etch reduction of the metal films. In FIG. 8, the slurry composition EX1 according to some implementations includes about 0.1 wt % silica as abrasive particles, about 5 wt % potassium iodate as an oxidizer, and deionized water, and the slurry composition CEX according to the comparative example includes about 0.1 wt % silica, about 5 wt % hydrogen peroxide as an oxidizer, and deionized water.

Referring to FIG. 8, in the case of the slurry composition EX1 according to some implementations, the SER of the metal film, for example, a tungsten film, is about 0 Å/min at a temperature of about 25° C., and the SER of the metal film is about 10 Å/min at a temperature of about 60° C. In the case of the slurry composition CEX according to the comparative example, the SER of the metal film, for example, the tungsten film, is about 60 Å/min at a temperature of about 25° C., and the SER of the metal film is about 800 Å/min at a temperature of about 60° C.

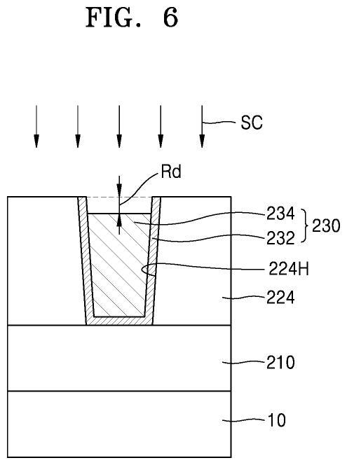

Referring to the results of FIG. 8, when the slurry composition EX1 according to some implementations is used, although the temperature of the slurry composition increases from about 25° C. to about 60° C., the SER of the metal film does not significantly increase and remains relatively low. However, when the slurry composition CEX according to the comparative example is used, the SER of the metal film increases significantly as the temperature of the slurry composition increases from about 25° C. to about 60° C. Accordingly, when the slurry composition CEX according to the comparative example is used, the SER of the metal film may increase significantly as the temperature of the slurry composition increases, the recess depth Rd (see FIG. 6) of the polished metal film may increase as the temperature increases, and thus the flatness of the metal film may be deteriorated. However, when the slurry composition EX1 according to some implementations is used, since the SER of the metal film does not significantly increase even when the temperature of the slurry composition increases, the depth of the recess of the polished metal film is small, and thus the flatness of the metal film may be improved.

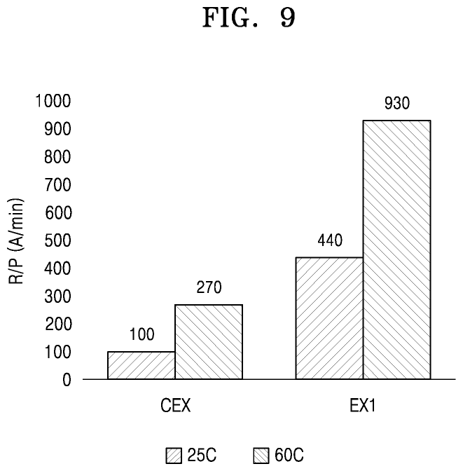

FIG. 9 is an example diagram illustrating a RR of a metal film according to the temperature of a slurry composition EX1, and a RR of a metal film according to the temperature of a slurry composition CEX according to a comparative example. In FIG. 9, the composition of the slurry composition EX1 according to some implementations and the composition of the slurry composition CEX according to the comparative example are the same as the composition of the slurry composition EX1 according to some implementations and the composition of the slurry composition CEX according to the comparative example in FIG. 8.

Referring to FIG. 9, in the case of the slurry composition EX1 according to some implementations, the RR of the metal film, for example, the tungsten film, is about 440 Å/min at a temperature of about 25° C., and the RR of the metal film is about 930 Å/min at a temperature of about 60° C. However, in the case of the slurry composition CEX according to the comparative example, the RR of the metal film, for example, the tungsten film, is about 100 Å/min at a temperature of about 25° C., and the RR of the metal film is about 270 Å/min at a temperature of about 60° C.

Referring to the results of FIG. 9, at both a relatively low temperature of about 25° C. and a relatively high temperature of about 60° C., the RR of the metal film when using the slurry composition EX1 according to some implementations is faster than the RR of the metal film when using the slurry composition CEX according to the comparative example.

That is, referring to the results of FIG. 8 and the results of FIG. 9 together, when using the slurry composition EX1 according to some implementations, a high RR of the metal film may be obtained while maintaining a relatively low SER of the metal film by increasing the temperature of the slurry composition from about 25° C. to about 60° C., but when using the slurry composition CEX according to the comparative example, although it is possible to increase the RR of the metal film by increasing the temperature of the slurry composition from about 25° C. to about 60° C., the SER of the metal film significantly increases, and the flatness of the metal film subjected to chemical mechanical polishing is deteriorated.

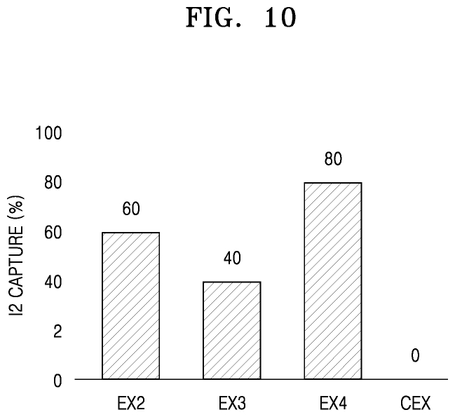

FIG. 10 is an example diagram illustrating a degree of iodine adsorption by an adsorbent included in each slurry composition EX2, EX3, and EX4, and a degree of iodine adsorption by an adsorbent included in a slurry composition CEX according to a comparative example. In FIG. 10, the first slurry composition EX2 includes about 0.1 wt % silica as abrasive particles, about 5 wt % potassium iodate as an oxidizer, deionized water, and about 1 wt % a silica zeolite (hereinafter referred to as a first silica zeolite) including a plurality of pores having a diameter of about 0.3 nm as an adsorbent, the second slurry composition EX3 includes about 0.1 wt % silica as abrasive particles, about 5 wt % potassium iodate as an oxidizer, deionized water, and about 1 wt % a silica zeolite (hereinafter referred to as a second silica zeolite) including a plurality of pores having a diameter of about 1 nm as an adsorbent, the third slurry composition EX4 includes about 0.1 wt % silica as abrasive particles, about 5 wt % potassium iodate as an oxidizer, deionized water, and about 1 wt % activated carbon as an adsorbent. In addition, the slurry composition CEX according to the comparative example includes about 0.1 wt % silica, about 5 wt % hydrogen peroxide as an oxidizer, and deionized water, but does not include an adsorbent.

Referring to FIG. 10, the first silica zeolite included in the first slurry composition EX2 is an adsorbent and adsorbs about 60% of iodine generated from the oxidizer during the chemical mechanical polishing process, the second silica zeolite included in the second slurry composition EX3 is an adsorbent and adsorbs about 40% of iodine generated from the oxidizer during the chemical mechanical polishing process, and the activated carbon included in the third slurry composition EX4 is an adsorbent and adsorbs about 80% of iodine generated from the oxidizer during the chemical mechanical polishing process. On the other hand, the slurry composition CEX according to the comparative example does not adsorb iodine generated from the oxidizer during the chemical mechanical polishing process since the slurry composition CEX does not separately include an adsorbent.

During the chemical mechanical polishing process, the iodine generated from the oxidizer may discolor and contaminate the abrasive pad 30 of the chemical mechanical polishing apparatus 20 illustrated in FIGS. 1 and 2. Referring to the results of FIG. 10, when the chemical mechanical polishing process is performed using the slurry compositions EX2, EX3, and EX4 according to some implementations, iodine generated from the oxidizer during the chemical mechanical polishing process may be removed, thereby preventing discoloration and contamination of the chemical mechanical polishing apparatus 20.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While the concepts described herein have been particularly shown and described with reference to implementations thereof, it will be understood that various changes in form and details may be made therein without departing from the spirit and scope of the following claims.

1. A slurry composition used for chemical mechanical polishing of a metal film, the slurry composition comprising:
abrasive particles;
deionized water; and
an oxidizer;
wherein the oxidizer comprises iodine, and the oxidizer is a temperature-sensitive oxidizer configured to control both a static etch rate and a removal rate of the metal film based on a polishing temperature during the chemical mechanical polishing being about 5° C. to about 100° C.

2. The slurry composition of claim 1,
wherein the oxidizer includes at least one of potassium iodate, sodium periodate, or periodic acid.

3. The slurry composition of claim 1,
wherein a concentration of the oxidizer is about 1 wt % to about 5 wt % of a total weight of the slurry composition.

4. The slurry composition of claim 1, further comprising
a pH adjusting agent, wherein the pH adjusting agent includes at least one of lithium hydroxide, sodium hydroxide, potassium hydroxide, cesium hydroxide, sulfuric acid, nitric acid, hydrogen chloride, or phosphoric acid.

5. The slurry composition of claim 1,
wherein a pH of the slurry composition is about 1 to about 5.

6. The slurry composition of claim 1,
wherein the abrasive particles include at least one of silica, alumina, ceria, titania, zirconia, magnesia, germania, or mangania.

7. The slurry composition of claim 6,
wherein a concentration of the abrasive particles is less than about 10 wt % of a total weight of the slurry composition.

8. The slurry composition of claim 1,
wherein the metal film comprises tungsten (W) or molybdenum (Mo).

9. A slurry composition used for chemical mechanical polishing of a metal film, the slurry composition comprising:
abrasive particles;
deionized water;
an oxidizer; and
an adsorbent;
wherein the oxidizer comprises iodine, and the adsorbent is configured to adsorb iodine generated from the oxidizer based on the chemical mechanical polishing.

10. The slurry composition of claim 9,
wherein a concentration of the adsorbent is less than or equal to about 1 wt % of a total weight of the slurry composition.

11. The slurry composition of claim 9,
wherein the adsorbent comprises porous material.

12. The slurry composition of claim 9,
wherein the adsorbent includes at least one of a metal organic framework (MOF), zeolite, or activated carbon.

13. The slurry composition of claim 9,
wherein the oxidizer is a temperature-sensitive oxidizer configured to control both a static etch rate and a removal rate of the metal film based on a polishing temperature during the chemical mechanical polishing being about 5° C. to about 100° C.

14. The slurry composition of claim 9,
wherein the oxidizer includes at least one of potassium iodate, sodium periodate, or periodic acid, and wherein a concentration of the oxidizer is about 1 wt % to about 5 wt % of a total weight of the oxidizer.

15. The slurry composition of claim 9,
wherein the slurry composition further comprises a pH adjusting agent, and
wherein the pH adjusting agent includes at least one of lithium hydroxide, sodium hydroxide, potassium hydroxide, cesium hydroxide, sulfuric acid, nitric acid, hydrogen chloride, or phosphoric acid.

16. The slurry composition of claim 9,
wherein a pH of the slurry composition is about 1 to about 5.

17. The slurry composition of claim 9,
wherein the metal film comprises tungsten (W) or molybdenum (Mo).

18. A slurry composition used for chemical mechanical polishing of a metal film, the metal film comprising tungsten (W), the slurry composition comprising:
abrasive particles;
deionized water;
an oxidizer comprising iodine;
an adsorbent comprising porous material; and
a pH adjusting agent;
wherein the oxidizer comprising iodine, the oxidizer is a temperature-sensitive oxidizer configured to control both a static etch rate and a removal rate of the metal film based on a polishing temperature during the chemical mechanical polishing being about 5° C. to about 100° C., and the adsorbent is configured to adsorb iodine generated from the oxidizer based on the chemical mechanical polishing.

19. The slurry composition of claim 18,
wherein the oxidizer includes at least one of potassium iodate, sodium periodate, or periodic acid.

20. The slurry composition of claim 18,
wherein the adsorbent includes at least one of a metal organic framework (MOF), zeolite, or activated carbon, and a concentration of the adsorbent is less than or equal to about 1 wt % of a total weight of the slurry composition.

21.-23. (canceled)
